(19) United States
(12) Patent Application Publication
(10) Pub. No.: US 2025/0117053 A1
(43) Pub. Date: Apr. 10, 2025

(54) IMAGE DISPLAY APPARATUS

(71) Applicant: FUJIFILM Corporation, Tokyo (JP)

(72) Inventor: Tetsu MIYOSHI, Minamiashigara-shi (JP)

(73) Assignee: FUJIFILM Corporation, Tokyo (JP)

(21) Appl. No.: 18/984,599

(22) Filed: Dec. 17, 2024

Related U.S. Application Data
(63) Continuation of application No. PCT/JP2023/022944, filed on Jun. 21, 2023.

(30) Foreign Application Priority Data
Jul. 8, 2022 (JP) 2022-110305

(51) Int. Cl. G06F 1/16; H04R 1/02; H04R 17/00

(52) U.S. Cl. CPC G06F 1/1688; H04R 1/025; H04R 17/005; H04R 2499/15

(57) ABSTRACT

An object is to provide an image display apparatus that outputs a voice by vibrating a display panel using a vibrator, in which a voice with sufficient sound pressure can be heard up to a high sound band. The object is achieved by including a display panel having a pixel pitch of 25 to 100 dpi and a vibrator mounted on a non-display surface of the display panel, in which, in a case where a length of a diagonal line of the display panel is denoted by A, a maximum length Lmax of the vibrator in a direction along a lateral direction of the display panel satisfies “Lmax≤(A/0.15)^{1/2}”.

### CROSS-REFERENCE TO RELATED APPLICATIONS

This application is a Continuation of PCT International Application No. PCT/JP2023/022944 filed on Jun. 21, 2023, which claims priority under 35 U.S.C. § 119(a) to Japanese Patent Application No. 2022-110305 filed on Jul. 8, 2022. The above applications are hereby expressly incorporated by reference, in their entirety, into the present application.

### BACKGROUND OF THE INVENTION

### 1. Field of the Invention

The present invention relates to an image display apparatus which outputs a voice using a vibrator.

### 2. Description of the Related Art

A vibrator, so-called exciter, which is attached by coming into contact with various articles serving as a vibration plate and makes a sound by vibrating the articles, has been used for various applications.

For example, in an office, by attaching the vibrator to a conference table, a whiteboard, a screen, or the like during presentation, telephone conference, or the like, voice can be output instead of using a speaker. In a vehicle such as an automobile, by attaching the vibrator to a console, an A pillar, a roof, or the like, a guide sound, a warning sound, music, or the like can be sounded. In addition, in an automobile which does not produce an engine sound, such as a hybrid vehicle and an electric vehicle, by attaching the vibrator to a bumper or the like, a vehicle approach warning sound can be produced from the bumper or the like.

In addition, in recent years, flat displays such as a liquid crystal display and an organic electroluminescence display (organic EL display) have been the mainstream in image display apparatuses.

An image display apparatus which outputs a voice by vibrating a display panel using a display panel used in such a thin display as a vibration plate and attaching a vibrator to a non-display surface of the display panel is also known.

For example, JP2021-090167 Å discloses an image display apparatus (display speaker) including a display panel, a vibrator, and a vibration weight, in which the vibrator is surface-bonded to the display panel, and the vibration weight is bonded to the vibrator. In JP2021-090167A, a piezoelectric element such as a piezo element is exemplified as the vibrator.

In the image display apparatus, the display panel is vibrated by the vibrator to output a voice, and the vibration weight is provided to output the voice with a sufficient sound pressure even in a low frequency band.

### SUMMARY OF THE INVENTION

In recent years, thin displays such as a liquid crystal display and an organic EL display tend to be enlarged.

Here, according to the study of the present inventor, in a case where a display is vibrated using a vibrator to output a voice as disclosed in JP2021-090167A, in a large display, even in a case where an image display apparatus is viewed at an appropriate viewing distance, a sound pressure in a high sound band may be low, and an image may not be viewed with an appropriate voice.

An object of the present invention is to solve the above-described problem of the related art, and to provide an image display apparatus that outputs a voice by vibrating a display panel using a vibrator, in which a voice with sufficient sound pressure can be heard up to a high sound band according to a size and a pixel pitch of the display panel in the image display apparatus.

In order to achieve such objects, the present invention has the following configurations.

[1] An image display apparatus comprising:
a display panel having a pixel pitch of 25 to 100 dpi; and
a vibrator mounted on a non-display surface of the display panel,
in which, in a case where a length of a diagonal line of the display panel is denoted by A, a maximum length Lmax of the vibrator in a direction along a lateral direction of the display panel satisfies Lmax≤(A/0.15)^{1/2}.

[2] An image display apparatus comprising:
a display panel having a pixel pitch of 50 to 200 dpi; and
a vibrator mounted on a non-display surface of the display panel,
in which, in a case where a length of a diagonal line of the display panel is denoted by A, a maximum length Lmax of the vibrator in a direction along a lateral direction of the display panel satisfies Lmax≤(A/0.3)^{1/2}.

[3] An image display apparatus comprising:
a display panel having a pixel pitch of 100 to 400 dpi; and
a vibrator mounted on a non-display surface of the display panel,
in which, in a case where a length of a diagonal line of the display panel is denoted by A, a maximum length Lmax of the vibrator in a direction along a lateral direction of the display panel satisfies Lmax≤(A/0.6)^{1/2}.

[4] The image display apparatus according to any one of [1] to [3],
in which an aspect ratio of the display panel is 16:9.

[5] The image display apparatus according to any one of [1] to [4],
in which the vibrator is a piezoelectric film having electrode layers on both surfaces of a piezoelectric layer.

[6] The image display apparatus according to [5],
in which the vibrator is obtained by laminating a plurality of layers of the piezoelectric film.

[7] The image display apparatus according to [5] or [6],
in which the piezoelectric film has a protective layer which covers the electrode layer.

[8] The image display apparatus according to any one of [5] to [7],
in which the piezoelectric layer is a polymer-based piezoelectric composite material having piezoelectric particles in a polymer material.

[9] The image display apparatus according to [8],
in which the polymer material has a cyanoethyl group.

[10] The image display apparatus according to [9],
in which the polymer material is cyanoethylated polyvinyl alcohol.

[11] The image display apparatus according to any one of [6] to [10],
in which the vibrator is obtained by folding one piezoelectric film to laminate the plurality of layers of the piezoelectric film.

[12] The image display apparatus according to any one of [6] to [11],
in which laminated adjacent piezoelectric films are bonded to each other by a bonding layer.

According to the present invention, in an image display apparatus that outputs a voice by vibrating a display panel using a vibrator, a voice with sufficient sound pressure can be heard up to a high sound band according to a size and a pixel pitch of the display panel in the image display apparatus.

### BRIEF DESCRIPTION OF THE DRAWINGS

FIG. 1 is a view conceptually showing an example of an image display apparatus according to an embodiment of the present invention.

FIG. 2 is a partially enlarged conceptual view of the image display apparatus shown in FIG. 1.

FIG. 3 is a view conceptually showing another example of a vibrator used in the image display apparatus according to the embodiment of the present invention.

FIG. 4 is a view conceptually showing an example of a piezoelectric film used in the vibrator.

FIG. 5 is a conceptual view for describing an example of a production method of the piezoelectric film.

FIG. 6 is a conceptual view for describing the example of the production method of the piezoelectric film.

FIG. 7 is a conceptual view for describing the example of the production method of the piezoelectric film.

FIG. 8 is a view conceptually showing an example of wiring line lead-out from the vibrator.

FIG. 9 is a conceptual diagram for describing a line array effect.

FIG. 10 is a graph showing a result of Example of the present invention.

FIG. 11 is a graph showing a result of Comparative Example of the present invention.

### DESCRIPTION OF THE PREFERRED EMBODIMENTS

Hereinafter, the image display apparatus according to the embodiment of the present invention will be described in detail based on suitable embodiments shown in the accompanying drawings.

Although configuration requirements to be described below are described based on representative embodiments of the present invention, the present invention is not limited to the embodiments.

In addition, drawings shown below are conceptual views for describing the image display apparatus according to the embodiment of the present invention. Therefore, the size, thickness, shape, positional relationship, and the like of each member and each site are different from the actual ones.

Any numerical range expressed using “to” in the present invention refers to a range including the numerical values before and after the “to” as a lower limit value and an upper limit value, respectively.

Furthermore, in the present invention, the terms “first” and “second” attached to an electrode layer, a protective layer, or the like are attached for convenience to distinguish two members which are basically the same as each other and describe the image display apparatus according to the embodiment of the present invention. Therefore, the terms “first” and “second” in these members have no technical meaning and are irrelevant to the actual usage state and the positional relationship therebetween.

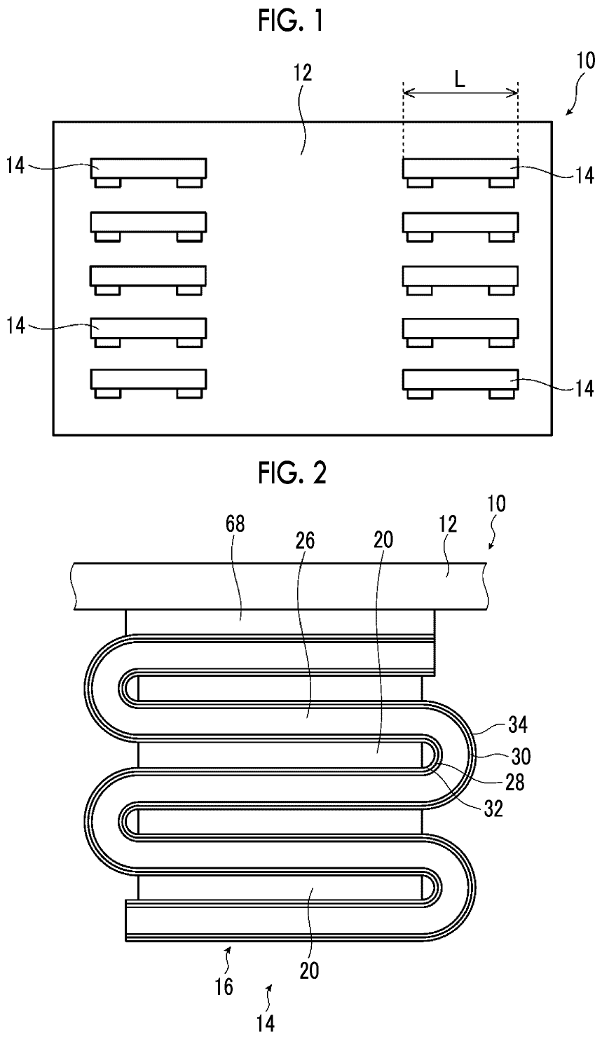

FIGS. 1 and 2 are views conceptually showing an example of the image display apparatus according to the embodiment of the present invention.

As shown in FIGS. 1 and 2, an image display apparatus 10 according to the embodiment of the present invention is obtained by mounting a vibrator 14 on a non-display surface (non-image display surface) of a display panel 12. The non-display surface is a surface on a back side of a display surface (image display surface) in the display panel 12. In the following description, the non-display surface of the display panel 12 is also referred to as a back surface of the display panel 12.

In the image display apparatus 10 shown in FIG. 1, there are two rows of five vibrators 14 arranged in a lateral direction of the display panel 12, the vibrators 14 being spaced apart in a longitudinal direction of the display panel 12.

For example, each of the rows of the vibrators 14 corresponds to a right channel and a left channel of the audio output to be stereo-reproduced.

In the image display apparatus 10 according to the embodiment of the present invention, the number and positions of the vibrators 14 mounted on the display panel 12 are not limited to the illustrated example, and various aspects can be used.

For example, the number of vibrators 14 in each row corresponding to the right channel and the left channel of the audio output to be stereo-reproduced may be 4 or less or 6 or more. In addition, each of the right channel and the left channel may have a plurality of rows of the vibrators.

In addition, the row of the vibrators 14 mounted on the display panel 12 may have one row or a plurality of rows corresponding to the audio output of monaural reproduction.

Furthermore, the image display apparatus 10 according to the embodiment of the present invention may have only one vibrator 14, or may have a plurality of vibrators 14 two-dimensionally regularly or irregularly arranged.

That is, in the image display apparatus 10 according to the embodiment of the present invention, the position, the number, and the like of the vibrators 14 mounted on the display panel 12 may be appropriately set according to the size, the application, and the like of the image display apparatus 10.

In the image display apparatus 10 according to the embodiment of the present invention, the display panel 12 is not limited, and various known display panels can be used.

In particular, a so-called thin type display panel used for a television, such as a liquid crystal display panel, an organic EL display panel (organic light emitting diode (OLED) display panel), a micro light emitting diode (LED) display panel, an inorganic EL display panel, and a plasma display panel, is suitably used.

Among these, a self-luminous display panel such as an OLED display panel is preferable from the viewpoint that a backlight is not necessary, the vibrator 14 described below can be directly mounted on the panel, and sound output can be suitably performed; and an OLED display panel is suitably used among these.

In a first aspect of the image display apparatus 10 according to the embodiment of the present invention, the display panel 12 has a pixel pitch (pixel density) of 25 to 100 dot per inch (dpi). The pixel pitch is a pixel pitch corresponding to a display panel of a so-called full high definition. The pixel pitch of the full high definition is 92 dpi for 23 inches and 30 dpi for 80 inches.

In addition, in a second aspect of the image display apparatus 10 according to the embodiment of the present invention, the display panel 12 has a pixel pitch of 50 to 200 dpi. The pixel pitch is a pixel pitch corresponding to a display panel of a so-called 4K television. The pixel pitch of the 4K television is 185 dpi for 23 inches and 60 dpi for 80 inches.

Furthermore, in a third aspect of the image display apparatus 10 of the embodiment of the present invention, the display panel 12 has a pixel pitch of 100 to 400 dpi. The pixel pitch is a pixel pitch corresponding to a display panel of a so-called 8K television. The pixel pitch of the 8K television is 370 dpi for 23 inches and 120 dpi for 80 inches.

In the image display apparatus 10 according to the embodiment of the present invention, an aspect ratio of the display panel is not limited, but is preferably 16:9 as in a normal display panel used for a television (television receiver), a computer display, or the like.

In the image display apparatus 10 according to the embodiment of the present invention, a shape of the display panel is not limited to a rectangular shape as in the illustrated example, and various shapes such as a square shape, a circular shape, an elliptical shape, and a trapezoidal shape can be used.

In the image display apparatus 10 of the illustrated example, the vibrator 14 is formed by laminating a piezoelectric film 16 in a plurality of layers by folding the piezoelectric film 16 having flexibility a plurality of times in a bellows shape.

The piezoelectric film 16 includes a first electrode layer 28 on one surface of a piezoelectric layer 26, a second electrode layer 30 on the other surface, a first protective layer 32 on a surface of the first electrode layer 28, and a second protective layer 34 on a surface of the second electrode layer 30. That is, the vibrator 14 in the illustrated example is a laminated piezoelectric element (laminated piezoelectric body).

In addition, in the vibrator 14, adjacent piezoelectric film 16 folded and laminated is bonded by a bonding layer 20.

The vibrator 14 in the illustrated example has five layers of the piezoelectric film 16 laminated by folding the rectangular (oblong) piezoelectric film 16 four times at equal intervals.

In the image display apparatus 10 according to the embodiment of the present invention, in a case where the rectangular piezoelectric film 16 is folded, a folding-back line formed by folding the piezoelectric film 16 may coincide with a longitudinal direction in the planar shape of the vibrator 14, or may coincide with a lateral direction. The planar shape of the vibrator 14 is a shape of the vibrator 14 in a case where the vibrator 14 is viewed in a lamination direction of the piezoelectric film 16.

In the following description, the folding-back line formed by folding the piezoelectric film 16, that is, a line of an outer apex of an end part of the folded-back portion is also referred to as “ridge line” for convenience.

For example, in a case where a rectangular piezoelectric film having a size of 25×20 cm is folded four times at intervals of 5 cm in a direction of 25 cm, a piezoelectric element having a planar shape of a rectangle (striped shape) of 5×20 cm, in which the piezoelectric film is laminated in five layers and a ridge line coincides with a longitudinal direction of 20 cm, is obtained (refer to FIG. 8). In addition, in a case where a rectangular piezoelectric film having a size of 100×5 cm is folded four times at intervals of 20 cm in a direction of 100 cm, a piezoelectric element having the same planar shape as a rectangle (striped shape) of 5×20 cm, in which the piezoelectric film is laminated in five layers and a ridge line coincides with a lateral direction of 5 cm, is obtained.

As a preferred aspect, the vibrator 14 shown in FIG. 1 is produced by folding the rectangular piezoelectric film 16, and thus has a rectangular planar shape. However, in the image display apparatus according to the embodiment of the present invention, the shape of the piezoelectric film 16 is not limited to the rectangle, and various shapes can be used.

Examples thereof include a circular shape, a rectangular shape with rounded corners (elongated shape), an elliptical shape, and a polygonal shape such as a hexagonal shape.

As described above, the vibrator 14 is formed by folding and laminating the piezoelectric film 16 a plurality of times. The vibrator 14 in the illustrated example has five layers of the piezoelectric film 16 laminated by folding the piezoelectric film 16 four times. In addition, the adjacent piezoelectric films 16 laminated are bonded to each other by the bonding layer 20.

In the image display apparatus 10 according to the embodiment of the present invention, since a plurality of piezoelectric films 16 are laminated and the adjacent piezoelectric films 16 are bonded, as compared with a case where one sheet of the piezoelectric film is used, stretching and contracting force as the piezoelectric element can be increased. As a result, for example, the display panel 12 as a vibration plate can be bent with a large force, and a voice with a high sound pressure can be output.

The laminated piezoelectric element as the vibrator used in the image display apparatus according to the embodiment of the present invention is not limited to the configuration in which one piezoelectric film 16 is laminated by folding the piezoelectric film 16 and the adjacent piezoelectric films 16 are bonded to each other by the bonding layer 20.

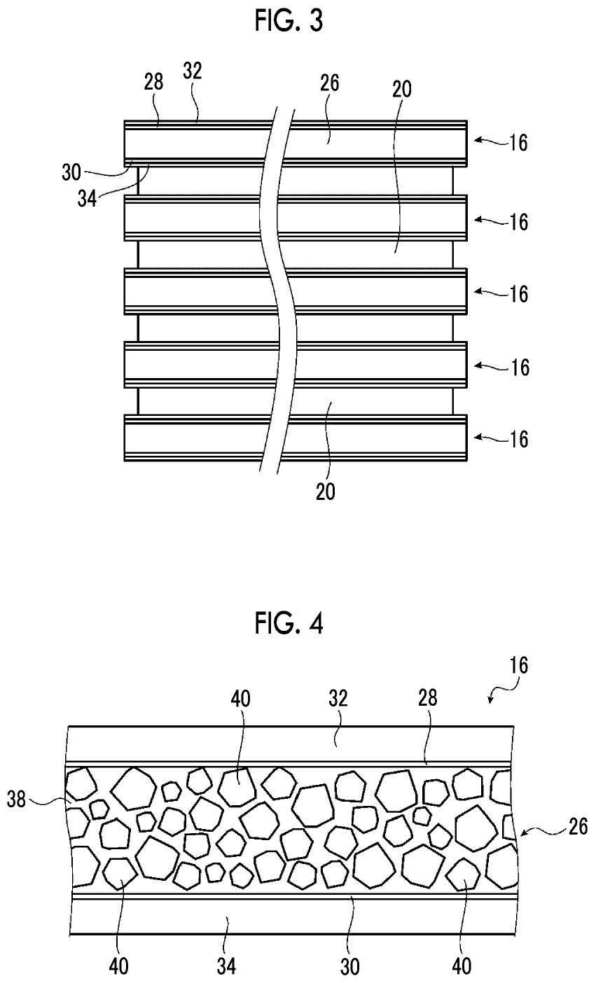

That is, as conceptually shown in FIG. 3, the vibrator used in the image display apparatus according to the embodiment of the present invention may have a configuration in which a plurality of cut sheet-like (single sheet-like) piezoelectric films 16 are laminated and adjacent piezoelectric films 16 are bonded to each other by the bonding layer 20.

In a case where the piezoelectric film 16 is laminated by folding one sheet of the piezoelectric film 16 as the vibrator 14 in the illustrated example, even though a plurality of piezoelectric films 16 are laminated, electrodes for driving the vibrator 14, that is, the piezoelectric film 16 can be led out at one location for each electrode layer to be described later. As a result, the vibrator 14 in which one sheet of the piezoelectric film 16 is folded and laminated can be simplified in configuration and in leading out of the electrodes, and further, productivity is also excellent.

In addition, in the vibrator 14, since one sheet of the piezoelectric film 16 is folded and laminated, electrode layers facing each other by the adjacent piezoelectric films by the lamination have the same polarity. As a result, the vibrator 14 is advantageous in that, even in a case where the electrode layers are in contact with each other, a short circuit is not generated.

In the image display apparatus 10 according to the embodiment of the present invention, the number of lamination of the piezoelectric film 16 in the vibrator 14 is not limited to the five layers in the illustrated example. That is, the image display apparatus 10 according to the embodiment of the present invention may be a piezoelectric element in which the piezoelectric film 16 is laminated in four or less layers by folding the piezoelectric film 16 three or less times, or may be a piezoelectric element in which the piezoelectric film 16 is laminated in six or more layers by folding the piezoelectric film 16 five or more times.

In the image display apparatus 10 according to the embodiment of the present invention, the number of lamination of the piezoelectric film 16 in the vibrator 14 is not limited, but is preferably 2 to 10 layers, more preferably 3 to 7 layers, and still more preferably 4 to 6 layers.

Regarding this point, the same applies to a configuration in which the cut sheet-like piezoelectric films 16 shown in FIG. 3 are laminated.

In the image display apparatus 10 according to the embodiment of the present invention, as the number of lamination of the piezoelectric film 16 increases, the output as a piezoelectric element increases, and as a result, a voice output with a high sound pressure can be performed. On the other hand, in a case where the number of laminations is small, there is a disadvantage in terms of the thickness of the vibrator 14, that is, the thickness of the image display apparatus 10.

Therefore, the number of layers of the piezoelectric film 16 in the vibrator 14 provided in the image display apparatus 10 according to the embodiment of the present invention may be appropriately set according to the strength of stiffness of the display panel 12, the size of the display panel 12, the bonding position on the display panel 12, the strength of stiffness of the piezoelectric film 16, the size of the vibrator 14 in the surface direction of the piezoelectric film, the sound pressure required for the image display apparatus 10, the thickness of the image display apparatus 10, and the like.

In the folded and laminated piezoelectric film 16 of the vibrator 14 in the illustrated example, piezoelectric films 16 adjacent to each other in the lamination direction are bonded to each other through the bonding layer 20.

By bonding the piezoelectric films 16 adjacent in the lamination direction with the bonding layer 20, stretch and contraction of each piezoelectric film 16 can be directly transmitted, and it is possible to drive without waste as a laminate of the laminated piezoelectric film 16.

In the present invention, as the bonding layer 20, various known bonding agents (bonding materials) can be used as long as the adjacent piezoelectric films 16 can be bonded.

Therefore, the bonding layer 20 may be a layer consisting of an adhesive (adhesive material), a layer consisting of a pressure sensitive adhesive (pressure sensitive adhesive material), or a layer consisting of a material having characteristics of both an adhesive and a pressure sensitive adhesive. The adhesive is a bonding agent which has fluidity in a case of bonding layers and is to be a solid state. In addition, the pressure sensitive adhesive is a bonding agent which is a gel-like (rubber-like) flexible solid in a case of bonding layers and whose gel-like state does not change thereafter.

Furthermore, the bonding layer 20 may be formed by applying a bonding agent having fluidity such as a liquid, or may also be formed by using a sheet-like bonding agent.

As will be described later, the vibrator 14 which is a laminated piezoelectric element expands and contracts a plurality of laminated piezoelectric films 16 to expand and contract itself, and bends and vibrates the display panel 12 as described later to output a sound. Therefore, in the vibrator 14, it is preferable that the stretch and contraction of each of the laminated piezoelectric film 16 is directly transmitted. In a case where a substance having viscosity, which relieves vibration, is present between the piezoelectric films 16, efficiency of transmitting the stretching and contracting energy of the piezoelectric film 16 is lowered, and driving efficiency of the vibrator 14 is also decreased.

In consideration of this point, it is preferable that the bonding layer 20 is an adhesive layer consisting of an adhesive from which a solid and hard bonding layer 20 is obtained, rather than a pressure sensitive adhesive layer consisting of a pressure sensitive adhesive. As a more preferred bonding layer 20, specifically, a bonding layer consisting of a thermoplastic type adhesive such as a polyester-based adhesive and a styrene-butadiene rubber (SBR)-based adhesive is suitably exemplified.

The adhesion, unlike pressure sensitive adhesion, is useful in a case where a high adhesion temperature is required. In addition, the thermoplastic type adhesive has “comparatively low temperature, short time, and strong adhesion”, which is suitable.

In the vibrator 14, a thickness of the bonding layer 20 is not limited, and a thickness capable of exhibiting sufficient bonding strength may be appropriately set depending on the forming material of the bonding layer 20.

Here, in the vibrator 14, as the bonding layer 20 is thinner, the effect of transmitting the stretching and contracting energy (vibration energy) of the piezoelectric layer 26 is higher, and the energy efficiency is higher. In addition, in a case where the bonding layer 20 is thick and has high rigidity, there is also a possibility that the stretch and contraction of the piezoelectric film 16 may be constrained.

In consideration of this point, it is preferable that the bonding layer 20 is thinner than the piezoelectric layer 26. That is, in the vibrator 14, the bonding layer 20 is preferably hard and thin. Specifically, the thickness of the bonding layer 20 is preferably 0.1 to 50 μm, more preferably 0.1 to 30 μm, and still more preferably 0.1 to 10 μm in terms of thickness after bonding.

In the image display apparatus 10 of the illustrated example, the vibrator 14 is bonded to the display panel 12 by a bonding layer 68.

Accordingly, the stretch and contraction of the vibrator 14 can be directly transmitted to the display panel 12, and the display panel 12 can be suitably vibrated.

In the image display apparatus 10 of the illustrated example, the bonding layer 68 for bonding the display panel 12 and the vibrator 14 is not limited, and various bonding agents can be used as long as the display panel 12 and the vibrator 14 (piezoelectric film 16) can be bonded to each other.

In the image display apparatus 10 according to the embodiment of the present invention, as the bonding layer 68 for bonding the display panel 12 and the vibrator 14 to each other, various agents as in the bonding layer 20 for bonding the adjacent piezoelectric films 16 described above can be used. In addition, the same applies to the preferred bonding layer 68.

In the image display apparatus 10 according to the embodiment of the present invention, a thickness of the bonding layer 68 is not limited, and a thickness capable of exhibiting sufficient bonding strength may be appropriately set depending on the forming material of the bonding layer 68.

Here, in the image display apparatus 10 according to the embodiment of the present invention, as the bonding layer 68 is thinner, the effect of transmitting the stretching and contracting energy (vibration energy) of the piezoelectric film 16 is higher, and the energy efficiency is higher. In addition, in a case where the bonding layer is thick and has high rigidity, there is also a possibility that the stretch and contraction of the vibrator 14 may be constrained.

In consideration of this point, the thickness of the bonding layer 68 for bonding the display panel 12 and the vibrator 14 is preferably 10 to 1,000 μm, more preferably 30 to 500 μm, and still more preferably 50 to 300 μm in terms of the thickness after bonding.

As described above, in the image display apparatus 10 of the illustrated example, the vibrator 14 is obtained by folding and laminating the piezoelectric film 16. Various known piezoelectric films 16 can be used as the piezoelectric film 16 as long as these films have flexibility which can be bent and stretched.

In the present invention, the expression of “having flexibility” is synonymous with having flexibility in the general interpretation, and indicates being capable of bending and being flexible, specifically, being capable of bending and stretching without causing breakage and damage.

In the image display apparatus 10 according to the embodiment of the present invention, as a preferred aspect, the piezoelectric film 16 includes electrode layers provided on both surfaces of the piezoelectric layer 26, and protective layers provided to cover the electrode layers.

FIG. 4 is a cross-sectional view conceptually showing an example of the piezoelectric film 16. In FIG. 4 and the like, hatching will be omitted in order to clarify the configuration by simplifying the drawing.

In the following description, a “cross section” indicates a cross section of the piezoelectric film in a thickness direction, unless otherwise specified. The thickness direction of the piezoelectric film is the lamination direction of the piezoelectric film.

As shown in FIG. 4, the piezoelectric film 16 in the illustrated example includes a piezoelectric layer 26, a first electrode layer 28 laminated on one surface of the piezoelectric layer 26, a first protective layer 32 laminated on the first electrode layer 28, a second electrode layer 30 laminated on the other surface of the piezoelectric layer 26, and a second protective layer 34 laminated the second electrode layer 30.

In the piezoelectric film 16, various known piezoelectric layers can be used as the piezoelectric layer 26.

In the piezoelectric film 16, as conceptually shown in FIG. 4, the piezoelectric layer 26 is preferably a polymer-based piezoelectric composite material including the piezoelectric particles 40 in the polymer matrix 38 including the polymer material.

Here, it is preferable that the polymer-based piezoelectric composite material (piezoelectric layer 26) satisfies the following requirements. In the present invention, normal temperature is in a range of 0° C. to 50° C.

### (i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

### (ii) Acoustic Quality

In a speaker, the piezoelectric particles vibrate at a frequency of an audio band of 20 Hz to 20 kHz, and vibration energy causes the entire vibration plate (polymer-based piezoelectric composite material) to vibrate integrally so that sound is reproduced. Therefore, in order to increase transmission efficiency of the vibration energy, the polymer-based piezoelectric composite material is required to have appropriate rigidity. In addition, in a case where frequency characteristics of the speaker are smooth, an amount of a change in acoustic quality decreases in a case where the lowest resonance frequency f₀ is changed in association with a change in curvature of the speaker. Therefore, the polymer-based piezoelectric composite material is required to have a suitably large loss tangent.

It has been known that the lowest resonance frequency f₀ of the vibration plate for a speaker is represented by the following expression. Here, s represents the stiffness of the vibration system, and m represents the mass.

$$Lowest resonance frequency : {f}_{0} = \frac{1}{2 π} \sqrt{\frac{s}{m}}$$

Here, as a degree of bending of the piezoelectric film, that is, a curvature radius of a bending portion increases, a mechanical stiffness s decreases, and thus the lowest resonance frequency f₀ decreases. That is, acoustic quality (volume and frequency characteristics) of the speaker changes depending on the curvature radius of the piezoelectric film.

Accordingly, the polymer-based piezoelectric composite material is required to exhibit a behavior of being rigid with respect to a vibration of 20 Hz to 20 kHz and being flexible with respect to a vibration of less than or equal to a few Hz. In addition, the loss tangent of the polymer-based piezoelectric composite material is required to be suitably large with respect to the vibration of all frequencies of 20 kHz or less.

In general, a polymer solid has a viscoelasticity relaxing mechanism, and a molecular movement with a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 26), the polymer-based piezoelectric composite material exhibiting a behavior of being rigid with respect to the vibration of 20 Hz to 20 kHz and being flexible with respect to the slow vibration of less than or equal to a few Hz is achieved by using, as a matrix, a polymer material having a glass transition point at normal temperature, that is, a polymer material having viscoelasticity at normal temperature. In particular, from the viewpoint that such a behavior is suitably exhibited, it is preferable that the polymer material in which the glass transition point Tg at a frequency of 1 Hz is at normal temperature is used for the matrix of the polymer-based piezoelectric composite material.

In the polymer material serving as the polymer matrix 38, it is preferable that the maximal value of a loss tangent Tan δ at a frequency of 1 Hz according to a dynamic viscoelasticity test at normal temperature is 0.5 or more.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In addition, in the polymer material serving as the polymer matrix 38, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 kHz.

In addition, it is more suitable that a relative permittivity of the polymer material serving as the polymer matrix 38 is 10 or more at 25° C. Accordingly, in a case where a voltage is applied to the polymer-based piezoelectric composite material, a higher electric field is applied to the piezoelectric particles in the polymer matrix, and thus a large deformation amount can be expected.

However, in consideration of ensuring favorable moisture resistance and the like, it is suitable that the relative permittivity of the polymer material is 10 or less at 25° C.

Suitable examples of the polymer material satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate.

In addition, as these polymer materials, a commercially available product such as Hybrar 5127 (manufactured by Kuraray Co., Ltd.) can also be suitably used.

Among these, as the polymer material constituting the polymer matrix 38, it is preferable to use a polymer material having a cyanoethyl group and particularly preferable to use cyanoethylated PVA. That is, in the piezoelectric film 16, as the polymer matrix 38 of the piezoelectric layer 26, it is preferable to use a polymer material containing a cyanoethyl group and particularly preferable to use cyanoethylated PVA.

In the following description, the above-described polymer materials typified by cyanoethylated PVA will also be collectively referred to as “polymer material having viscoelasticity at normal temperature”.

These polymer materials having viscoelasticity at normal temperature may be used alone or in combination (mixture) of two or more kinds thereof.

In the piezoelectric film 16, a plurality of polymer materials may be used in combination as necessary for the polymer matrix 38 of the piezoelectric layer 26.

That is, for the purpose of adjustment of dielectric characteristics, mechanical characteristics, or the like, other dielectric polymer materials may be added to the polymer matrix 38 constituting the polymer-based piezoelectric composite material in addition to the polymer material having viscoelasticity at normal temperature, as necessary.

Examples of the dielectric polymer material which can be added thereto include fluorine-based polymers such as polyvinylidene fluoride (PVDF), a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among these, a polymer material having a cyanoethyl group is suitably used.

In addition, in the polymer matrix 38 of the piezoelectric layer 26, the number of these dielectric polymer materials is not limited to one, and a plurality of kinds of dielectric polymer materials may be added.

In addition, for the purpose of adjusting the glass transition point Tg of the polymer matrix 38, a thermoplastic resin such as a vinyl chloride resin, polyethylene, polystyrene, a methacrylic resin, polybutene, and isobutylene, a thermosetting resin such as a phenol resin, a urea resin, a melamine resin, an alkyd resin, and mica, or the like may be added, in addition to the dielectric polymer material.

Furthermore, for the purpose of improving pressure sensitive adhesiveness, a viscosity imparting agent such as rosin ester, rosin, terpene, terpene phenol, and a petroleum resin may be added.

In the polymer matrix 38 of the piezoelectric layer 26, the addition amount in a case of adding polymer materials other than the polymer material having viscoelasticity at normal temperature is not particularly limited, but is preferably set to 30% by mass or less in terms of the proportion of the polymer materials in the polymer matrix 38.

In this manner, characteristics of the polymer material to be added can be exhibited without impairing the viscoelasticity relaxing mechanism in the polymer matrix 38, so that preferred results such as an increase in permittivity, improvement of heat resistance, and improvement of adhesiveness between the piezoelectric particles 40 and the electrode layer can be obtained.

The polymer-based piezoelectric composite material serving as the piezoelectric layer 26 contains the piezoelectric particles 40 in the polymer matrix. The piezoelectric particles 40 are dispersed in the polymer matrix, preferably dispersed uniformly (substantially uniform).

It is preferable that the piezoelectric particles 40 consist of ceramic particles having a perovskite type or wurtzite type crystal structure.

Examples of the ceramic particles constituting the piezoelectric particles 40 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

A particle diameter of the piezoelectric particles 40 may be appropriately selected according to the size and the applications of the piezoelectric film 16. The particle diameter of the piezoelectric particles 40 is preferably 1 to 10 μm.

By setting the particle diameter of the piezoelectric particles 40 to be within the above-described range, preferred results in terms of achieving both excellent piezoelectric characteristics and flexibility can be obtained.

In the piezoelectric film 16, the ratio between the amount of the polymer matrix 38 and the amount of the piezoelectric particles 40 in the piezoelectric layer 26 may be appropriately set according to the size and the thickness of the piezoelectric film 16 in the plane direction, the applications of the piezoelectric film 16, the characteristics required for the piezoelectric film 16, and the like.

A volume fraction of the piezoelectric particles 40 in the piezoelectric layer 26 is preferably 30% to 80% and more preferably 50% to 80%.

By setting the ratio between the amount of the polymer matrix 38 and the amount of the piezoelectric particles 40 to be within the above-described range, preferred results in terms of achieving both of excellent piezoelectric characteristics and flexibility can be obtained.

In the piezoelectric film 16, a thickness of the piezoelectric layer 26 is not limited and may be appropriately set according to the size of the piezoelectric film 16, the applications of the piezoelectric film 16, the characteristics required for the piezoelectric film 16, and the like.

The thickness of the piezoelectric layer 26 is preferably 8 to 300 μm, more preferably 8 to 200 μm, still more preferably 10 to 150 am, and particularly preferably 15 to 100 am.

By setting the thickness of the piezoelectric layer 26 to be within the above-described ranges, preferred results in terms of achieving both ensuring of the rigidity and moderate elasticity can be obtained.

Furthermore, the thickness of the piezoelectric layer 26 is preferably 45 μm or more. It is more preferable that the thickness of the piezoelectric layer 26 is 45 am or more in the above-described range.

From the viewpoint of obtaining stabilized vibrator 14 having high output (high stretching and contracting force), reducing the number of lamination of the piezoelectric film 16 to thinning the piezoelectric element, and suppressing power consumption during driving of the piezoelectric element, it is preferable that the thickness of the piezoelectric layer 26 is set to 45 μm or more.

The same applies to a case where the piezoelectric layer 26 is not the polymer-based piezoelectric composite material. However, in a case where the piezoelectric layer 26 is the polymer-based piezoelectric composite material, it is more preferable to set the thickness of the piezoelectric layer 26 to be 45 m or more in order to obtain the above-described advantages and to ensure sufficient flexibility of the piezoelectric film 16.

It is preferable that the piezoelectric layer 26 is subjected to a polarization treatment (poling) in the thickness direction. The polarization treatment will be described later in detail.

In the piezoelectric film 16, the piezoelectric layer 26 is not limited to the polymer-based piezoelectric composite material containing the piezoelectric particles 40 in the polymer matrix 38 consisting of a polymer material having viscoelasticity at normal temperature, such as cyanoethylated PVA, as described above.

That is, in the piezoelectric film 16, various known piezoelectric layers can be used as the piezoelectric layer.

As an example, a polymer-based piezoelectric composite material containing the same piezoelectric particles 40 in a matrix containing a dielectric polymer material such as polyvinylidene fluoride, a vinylidene fluoride-tetrafluoroethylene copolymer, and a vinylidene fluoride-trifluoroethylene copolymer described above, a piezoelectric layer consisting of polyvinylidene fluoride, a piezoelectric layer consisting of a fluororesin other than polyvinylidene fluoride, a piezoelectric layer obtained by laminating a film consisting of poly-L lactic acid and a film consisting of poly-D lactic acid, and the like are also available.

However, as described above, from the viewpoint that the polymer-based piezoelectric composite material can behave hard for vibrations at 20 Hz to 20 kHz and behave softly for slow vibrations at less than or equal to a few Hz, has excellent acoustic characteristics, and has excellent flexibility, a polymer-based piezoelectric composite material containing piezoelectric particles 40 in a polymer matrix 38 consisting of a polymer material having viscoelasticity at normal temperature, such as cyanoethylated PVA described above, is suitably used.

The piezoelectric film 16 shown in FIG. 4 has a configuration in which the second electrode layer 30 is provided on one surface of such a piezoelectric layer 26, the second protective layer 34 is provided on a surface of the second electrode layer 30, the first electrode layer 28 is provided on the other surface of the piezoelectric layer 26, and the first protective layer 32 is provided on a surface of the first electrode layer 28. In the piezoelectric film 16, the first electrode layer 28 and the second electrode layer 30 form an electrode pair.

In other words, the laminated film constituting the piezoelectric film 16 has a configuration in which both surfaces of the piezoelectric layer 26 are sandwiched between the electrode pair, that is, the first electrode layer 28 and the second electrode layer 30, and further sandwiched between the first protective layer 32 and the second protective layer 34.

In this manner, a region sandwiched between the first electrode layer 28 and the second electrode layer 30 is driven according to the applied voltage.

The piezoelectric film 16 may include, in addition to those layers, for example, a bonding layer for bonding the electrode layer and the piezoelectric layer 26 to each other, and a bonding layer for bonding the electrode layer and the protective layer to each other.

The bonding agent may be an adhesive or a pressure sensitive adhesive. In addition, the same material as the polymer material obtained by removing the piezoelectric particles 40 from the piezoelectric layer 26, that is, the polymer matrix 38 can also be suitably used as the bonding agent. The bonding layer may be provided on both the first electrode layer 28 side and the second electrode layer 30 side, or may be provided only on one of the first electrode layer 28 side or the second electrode layer 30 side.

The first protective layer 32 and the second protective layer 34 in the piezoelectric film 16 have a function of coating the first electrode layer 28 and the second electrode layer 30 and imparting moderate rigidity and mechanical strength to the piezoelectric layer 26. That is, the piezoelectric layer 26 containing the polymer matrix 38 and the piezoelectric particles 40 in the piezoelectric film 16 exhibits extremely excellent flexibility under bending deformation at a slow vibration, but may have insufficient rigidity or mechanical strength depending on the applications. As a compensation for this, the piezoelectric film 16 is provided with the first protective layer 32 and the second protective layer 34.

The first protective layer 32 and the second protective layer 34 have the same configuration despite of different disposition positions. Accordingly, in the following description, in a case where it is not necessary to distinguish the first protective layer 32 from the second protective layer 34, both members are collectively referred to as a protective layer.

The protective layer is not limited, and various sheet-like materials can be used as the protective layer, and suitable examples thereof include various resin films. Among these, from the viewpoint of excellent mechanical characteristics and heat resistance, a resin film consisting of polyethylene terephthalate (PET), polypropylene (PP), polystyrene (PS), polycarbonate (PC), polyphenylene sulfite (PPS), polymethylmethacrylate (PMMA), polyetherimide (PEI), polyimide (PI), polyamide (PA), polyethylene naphthalate (PEN), triacetyl cellulose (TAC), a cyclic olefin-based resin, and the like is suitably used.

A thickness of the protective layer is not limited. In addition, the thicknesses of the first protective layer 32 and the second protective layer 34 are basically the same as each other, but may be different from each other.

Here, in a case where the rigidity of the protective layer is extremely high, not only is the stretch and contraction of the piezoelectric layer 26 constrained, but also the flexibility is impaired. Therefore, it is advantageous that the thickness of the protective layer decrease except for a case where the mechanical strength or excellent handleability as a sheet-like material is required.

In a case where the thickness of the first protective layer 32 and the thickness of the second protective layer 34 are each twice or less the thickness of the piezoelectric layer 26, preferred results from the viewpoints of achieving both ensuring of the rigidity and moderate elasticity, and the like can be obtained.

For example, in a case where the thickness of the piezoelectric layer 26 is 50 μm and the first protective layer 32 and the second protective layer 34 consist of PET, the thicknesses of the first protective layer 32 and the second protective layer 34 are each preferably 100 m or less, more preferably 50 μm or less, and still more preferably 25 μm or less.

In the present invention, the first protective layer 32 and the second protective layer 34 are used as a preferred aspect, and are not essential configuration requirements. Therefore, the piezoelectric film 16 may include only the first protective layer 32, may include only the second protective layer 34, or may include no protective layer.

However, in consideration of mechanical strength of the piezoelectric film 16, protective property of the electrode layer, and the like, it is preferable that the piezoelectric film includes at least one protective layer, and it is more preferable to include two protective layers to cover both electrode layers, as shown in the illustrated example.

In the piezoelectric film 16, the first electrode layer 28 is formed between the piezoelectric layer 26 and the first protective layer 32, and the second electrode layer 30 is formed between the piezoelectric layer 26 and the second protective layer 34. The first electrode layer 28 and the second electrode layer 30 are for applying a voltage to the piezoelectric layer 26. The piezoelectric film 16 stretches and contracts by applying a voltage from the electrode layer to the piezoelectric layer 26.

The first electrode layer 28 and the second electrode layer 30 are basically the same, except that the positions are different. Accordingly, in the following description, in a case where it is not necessary to distinguish the first electrode layer 28 and the second electrode layer 30, both members are collectively referred to as an electrode layer.

In the piezoelectric film, a forming material of the electrode layer is not limited, and various conductors can be used as the forming material. Specific examples thereof include conductive polymers such as carbon, palladium, iron, tin, aluminum, nickel, platinum, gold, silver, copper, chromium, molybdenum, alloys thereof, indium tin oxide, and polyethylene dioxythiophene-polystyrene sulfonic acid (PEDOT/PPS).

Among these, copper, aluminum, gold, silver, platinum, or indium tin oxide is suitably exemplified. Among these, from the viewpoint of the conductivity, the cost, and the flexibility, copper is more preferable.

In addition, a method of forming the electrode layer is not limited, and various known methods, for example, a vapor-phase deposition method (a vacuum film forming method) such as vacuum vapor deposition or sputtering, a film forming method using plating, a method of bonding a foil formed of the materials described above, and a coating method can be used.

Among these, particularly from the viewpoint of ensuring the flexibility of the piezoelectric film 16, a thin film made of copper or aluminum formed by vacuum vapor deposition is suitably used as the electrode layer. Among these, a thin film made of copper, which is formed by vacuum vapor deposition, is particularly suitably used.

Thicknesses of the first electrode layer 28 and the second electrode layer 30 are not limited. In addition, the thicknesses of the first electrode layer 28 and the second electrode layer 30 are basically the same as each other, but may be different from each other.

Here, similarly to the protective layer described above, in a case where the rigidity of the electrode layer is extremely high, not only is the stretch and contraction of the piezoelectric layer 26 constrained, but also the flexibility is impaired. Therefore, it is advantageous that the thickness of the electrode layer is reduced in a case where an electric resistance is not excessively high.

In the piezoelectric film 16, it is suitable that a product of the thickness of the electrode layer and the Young's modulus thereof is less than a product of the thickness of the protective layer and the Young's modulus thereof because the flexibility is not considerably impaired.

As an example, a combination in which the protective layer is PET and the electrode layer consists of copper will be specifically described. A Young's modulus of the PET is approximately 6.2 GPa, and a Young's modulus of the copper is approximately 130 GPa. Therefore, in the combination, in a case where the thickness of the protective layer is 25 μm, a thickness of the electrode layer is preferably 1.2 μm or less, more preferably 0.3 μm or less, and still more preferably 0.1 μm or less.

The piezoelectric film 16 has a configuration in which the piezoelectric layer 26 is sandwiched between the first electrode layer 28 and the second electrode layer 30, and this laminate is further sandwiched between the first protective layer 32 and the second protective layer 34.

It is preferable that, in such a piezoelectric film 16, the maximal value at which the loss tangent (Tan δ) at a frequency of 1 Hz according to dynamic viscoelasticity measurement is 0.1 or more is present at normal temperature.

In this manner, even in a case where the piezoelectric film 16 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In the piezoelectric film 16, it is preferable that the storage elastic modulus (E′) at a frequency of 1 Hz according to the dynamic viscoelasticity measurement is 10 to 30 GPa at 0° C. and 1 to 10 GPa at 50° C.

In such a manner, the piezoelectric film 16 may have large frequency dispersion in the storage elastic modulus (E′) at normal temperature. That is, the piezoelectric film 16 can exhibit a behavior of being rigid with respect to the vibration of 20 Hz to 20 kHz and being flexible with respect to the vibration of less than or equal to a few Hz.

In the piezoelectric film 16, it is preferable that a product of the thickness and the storage elastic modulus (E′) at a frequency of 1 Hz according to the dynamic viscoelasticity measurement is 1.0×10⁶ to 2.0×10⁶ N/m at 0° C. and 1.0×10⁵ to 1.0×10⁶ N/m at 50° C.

In this manner, the piezoelectric film 16 may have moderate rigidity and mechanical strength within a range not impairing the flexibility and the acoustic characteristics.

Furthermore, in the piezoelectric film 16, it is preferable that the loss tangent (Tan δ) at a frequency of 1 kHz at 25° C. is 0.05 or more in a master curve obtained from the dynamic viscoelasticity measurement.

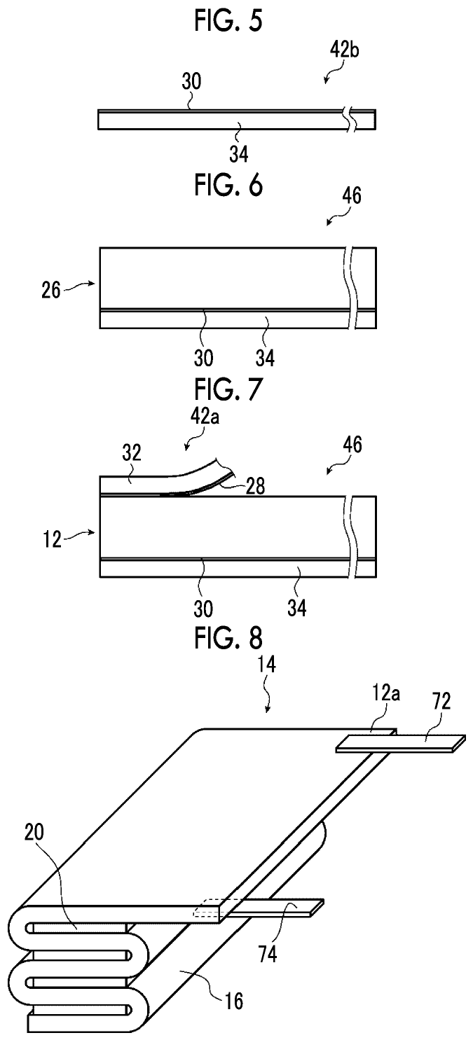

Next, an example of a manufacturing method of the piezoelectric film 16 will be described with reference to FIGS. 5 to 7.

First, as conceptually shown in FIG. 5, a sheet-like material 42b in which the second electrode layer 30 has been formed on a surface of the second protective layer 34 is prepared. Furthermore, as conceptually shown in FIG. 7, a sheet-like material 42a in which the first electrode layer 28 has been formed on a surface of the first protective layer 32 is prepared.

The sheet-like material 42b may be produced by forming a copper thin film or the like as the second electrode layer 30 on the surface of the second protective layer 34 using vacuum vapor deposition, sputtering, plating, or the like. Similarly, the sheet-like material 42a may be produced by forming a copper thin film or the like as the first electrode layer 28 on the surface of the first protective layer 32 using vacuum vapor deposition, sputtering, plating, or the like.

Alternatively, a commercially available sheet-like material in which a copper thin film or the like is formed on a protective layer may be used as the sheet-like material 42b and/or the sheet-like material 42a.

The sheet-like material 42b and the sheet-like material 42a may be exactly the same or different from each other.

In a case where the protective layer is extremely thin and thus the handleability is degraded, the protective layer with a separator (temporary support) may be used as necessary. PET having a thickness of 25 to 100 μm, or the like can be used as the separator. The separator may be removed after thermal compression bonding of the electrode layer and the protective layer.

Next, as conceptually shown in FIG. 6, a laminate 46 is produced by forming the piezoelectric layer 26 on the second electrode layer 30 of the sheet-like material 42b, and laminating the sheet-like material 42b and the piezoelectric layer 26.

The piezoelectric layer 26 may be formed by a known method with the piezoelectric layer 26.

For example, in a case of the piezoelectric layer (polymer-based piezoelectric composite material layer) in which the piezoelectric particles 40 are dispersed in the polymer matrix 38 shown in FIG. 4, the piezoelectric layer is produced as follows by way of an example.

First, the coating material is prepared by dissolving the above-described polymer material such as cyanoethylated PVA in an organic solvent, adding the piezoelectric particles 40 such as PZT particles thereto, and stirring the solution. The organic solvent is not limited, and various organic solvents such as dimethylformamide (DMF), methyl ethyl ketone, and cyclohexanone can be used.

In a case where the sheet-like material 42b is prepared and the coating material is prepared, the coating material is cast (applied) onto the sheet-like material 42b, and the organic solvent is evaporated and dried. In this manner, as shown in FIG. 6, the laminate 46 in which the second electrode layer 30 is provided on the second protective layer 34 and the piezoelectric layer 26 is laminated on the second electrode layer 30 is produced.

A casting method of the coating material is not limited, and all known methods (coating devices) such as a bar coater, a slide coater, and a doctor knife can be used.

Alternatively, in a case where the polymer material is a material that can be heated and melted, the laminate 46 as shown in FIG. 6 may be produced by heating and melting the polymer material to produce a melt obtained by adding the piezoelectric particles 40 to the melted material, extruding the melt on the sheet-like material 42b shown in FIG. 5 in a sheet shape by carrying out extrusion molding or the like, and cooling the laminate.

As described above, in the piezoelectric layer 26, a polymer piezoelectric material such as PVDF may be added to the polymer matrix 38, in addition to the polymer material having viscoelasticity at normal temperature.

In a case where the polymer piezoelectric material is added to the polymer matrix 38, the polymer piezoelectric material to be added to the above-described coating material may be dissolved. Alternatively, the polymer piezoelectric material to be added may be added to the heated and melted polymer material having viscoelasticity at normal temperature so that the polymer piezoelectric material is heated and melted.

After forming the piezoelectric layer 26, a calender treatment may be performed as necessary. The calender treatment may be performed once or a plurality of times.

As is well known, the calender treatment is a treatment in which the surface to be treated is pressed while being heated by a heating press, a heating roller, a heating roller pair, or the like to flatten the surface.

In addition, the piezoelectric layer 26 of the laminate 46 including the second electrode layer 30 on the second protective layer 34 and including the piezoelectric layer 26 formed on the second electrode layer 30 is subjected to a polarization treatment (poling).

A method of performing the polarization treatment on the piezoelectric layer 26 is not limited, and a known method can be used. For example, electric field poling in which a DC electric field is directly applied to a target to be subjected to the polarization treatment is exemplified. In a case of performing the electric field poling, the electric field poling treatment may be performed using the first electrode layer 28 and the second electrode layer 30 by forming the first electrode layer 28 before the polarization treatment.

In addition, in a case where the piezoelectric film 16 is produced, it is preferable that the polarization treatment is performed in the thickness direction instead of the plane direction of the piezoelectric layer 26.

Next, as conceptually shown in FIG. 7, the sheet-like material 42a which has been prepared in advance is laminated on the piezoelectric layer 26 side of the laminate 46 such that the first electrode layer 28 faces the piezoelectric layer 26.

Furthermore, the laminate is subjected to thermal compression bonding using a heating press device, a heating roller, or the like such that the laminate is sandwiched between the first protective layer 32 and the second protective layer 34, thereby bonding the laminate 46 and the sheet-like material 42a.

In this manner, the piezoelectric film 16 consisting of the piezoelectric layer 26, the first electrode layer 28 and the second electrode layer 30 provided on both surfaces of the piezoelectric layer 26, and the first protective layer 32 and the second protective layer 34 formed on the surfaces of the electrode layers is produced.

The piezoelectric film 16 to be produced in the above-described manner is polarized in the thickness direction instead of the plane direction, and thus excellent piezoelectric characteristics are obtained even in a case where a stretching treatment is not performed after the polarization treatment. Therefore, the piezoelectric film 16 has no in-plane anisotropy as a piezoelectric characteristic, and stretches and contracts isotropically in all directions in the plane direction in a case where a driving voltage is applied.

As described above, the vibrator 14 is formed by laminating the piezoelectric film in a plurality of layers by folding the piezoelectric film 16, in which the adjacent laminated piezoelectric films 16 are bonded through the bonding layer 20. Alternatively, as shown in FIG. 2, a plurality of cut sheet-like piezoelectric films 16 are laminated and adjacent laminated piezoelectric films 16 are bonded to each other by the bonding layer 20.

In the image display apparatus 10 according to the embodiment of the present invention, the piezoelectric layer 26 stretches and contracts by applying a driving voltage to the first electrode layer 28 and the second electrode layer 30. For that purpose, it is necessary to electrically connect the first electrode layer 28 and the second electrode layer 30 to an external device such as an external power supply.

As a method of connecting the first electrode layer 28 and the second electrode layer 30 to an external device, various known methods can be used.

As an example, as conceptually shown in FIG. 8, the piezoelectric film 16 is extended at one end part to provide a protruding portion 12a protruding from a region in which the piezoelectric film 16 is laminated. In addition, a method of providing a lead-out wire for electrically connecting the protruding portion 12a to an external device is exemplified.

In the present invention, the protruding portion specifically indicates a region of a single layer which does not overlap with other piezoelectric films 16 in the planar shape, that is, in a case of being viewed from the lamination direction.

In FIG. 8, the vibrator 14 in which one sheet of the piezoelectric film 16, shown in FIG. 1, is folded and laminated is exemplified, but in the configuration in which the cut sheet-like piezoelectric films 16 are laminated as shown in FIG. 2, the lead-out wire for connection to the external device may be provided for each piezoelectric film 16 in the same manner.

As shown in FIG. 8, a first lead-out wire 72 and a second lead-out wire 74 for electrically connecting to an external device such as a power supply device are connected to the protruding portion 12a of the vibrator 14.

The first lead-out wire 72 is a wiring line electrically led out from the first electrode layer 28, and the second lead-out wire 74 is a wiring line electrically led out from the second electrode layer 30. In the following description, in a case where it is unnecessary to distinguish between the first lead-out wire 72 and the second lead-out wire 74, the both lead-out wires are also simply referred to as a lead-out wire.

In the image display apparatus 10 according to the embodiment of the present invention, a connection method between the electrode layer and the lead-out wire, that is, a lead-out method is not limited, and various methods can be used.

As an example, a method in which a through-hole is formed in the protective layer, an electrode connecting member formed of a metal paste such as a silver paste is provided so as to fill the through-hole, and a lead-out wire is provided in the electrode connecting member is exemplified.

As another method, a method in which a rod-like or sheet-like lead-out electrode is provided between the electrode layer and the piezoelectric layer or between the electrode layer and the protective layer, and the lead-out electrode is connected to a lead-out wire is exemplified. Alternatively, the lead-out wire may be inserted directly between the electrode layer and the piezoelectric layer, or between the electrode layer and the protective layer, and the lead-out wire may be connected to the electrode layer.

As another method, a method in which a part of the protective layer and the electrode layer is projected from the piezoelectric layer in the plane direction, and a lead-out wire is connected to the projected electrode layer is exemplified. The lead-out wire and the electrode layer may be connected by a known method such as a method using a metal paste such as a silver paste, a method using a solder, and a method using a conductive adhesive.

Examples of a suitable method of leading out the electrodes include the method described in JP2014-209724A and the method described in JP2016-015354A.

In addition, in the vibrator 14, instead of extending the end part of the piezoelectric film 16, as shown in FIG. 18 of WO2020/095812A, a protruding portion such as an islet, protruding from the piezoelectric film in the direction of the ridge line of the piezoelectric film 16, that is, perpendicular to the folding-back direction, may be provided, and a lead-out wiring line may be provided for connecting an external device to the protruding portion.

Furthermore, in the image display apparatus according to the embodiment of the present invention, a plurality of these protruding portions may be used in combination as necessary.

The image display apparatus 10 according to the embodiment of the present invention is a sound output device which outputs a sound by vibrating a vibration plate with a vibrator (exciter), and outputs a sound using the display panel 12 as the vibration plate.

As described above, in the image display apparatus 10 according to the embodiment of the present invention, the piezoelectric film 16 is formed by sandwiching the piezoelectric layer 26 between the first electrode layer 28 and the second electrode layer 30.

In the piezoelectric layer 26, it is preferable that the piezoelectric particles 40 are dispersed in the polymer matrix 38.

In a case where a voltage is applied to the second electrode layer 30 and the first electrode layer 28 of the piezoelectric film 16 including such a piezoelectric layer 26, the piezoelectric particles 40 stretch and contract in the polarization direction according to the applied voltage. As a result, the piezoelectric film 16 (piezoelectric layer 26) contracts in the thickness direction. At the same time, the piezoelectric film 16 stretches and contracts in the plane direction due to the Poisson's ratio.

A degree of stretch and contraction is approximately 0.01% to 0.1%.

As described above, the thickness of the piezoelectric layer 26 is preferably approximately 8 to 300 km. Accordingly, the degree of stretch and contraction in the thickness direction is as extremely small as approximately 0.3 μm at the maximum.

On the contrary, the piezoelectric film 16, that is, the piezoelectric layer 26, has a size much larger than the thickness in a plane direction. Therefore, for example, in a case where a length of the piezoelectric film 16 is 20 cm, the piezoelectric film 16 stretches and contracts by a maximum of approximately 0.2 mm by the application of the voltage.

As described above, the vibrator 14 is formed by laminating the piezoelectric film 16 in five layers by folding the piezoelectric film 16. In addition, the vibrator 14 is bonded to the display panel 12 by the bonding layer 68.

The vibrator 14 also stretches and contracts in the same direction by the stretch and contraction of the piezoelectric film 16. The display panel 12 is bent by the stretch and contraction of the vibrator 14, and as a result, vibrates in the thickness direction.

The display panel 12 outputs a sound due to the vibration in the thickness direction. That is, the display panel 12 vibrates according to the magnitude of the voltage (driving voltage) applied to the piezoelectric film 16, and outputs a sound according to the driving voltage applied to the piezoelectric film 16.

Here, it has been known that, in a case where a general piezoelectric film consisting of a polymer material such as PVDF is stretched in a uniaxial direction after being subjected to the polarization treatment, molecular chains are aligned with respect to the stretching direction, and as a result, high piezoelectric characteristics are obtained in the stretching direction. Therefore, a typical piezoelectric film has in-plane anisotropy as a piezoelectric characteristic and has anisotropy in the amount of stretch and contraction in the plane direction in a case where a voltage is applied.

On the other hand, since the piezoelectric film 16 consisting of a polymer-based piezoelectric composite material in which the piezoelectric particles 40 are dispersed in the polymer matrix 38 as shown in FIG. 4 has large piezoelectric characteristics without stretching treatment after the polarization treatment, the piezoelectric film 16 has no in-plane anisotropy as a piezoelectric characteristic, and stretches and contracts isotropically in all directions in the plane direction. That is, the piezoelectric film 16 shown in FIG. 4 constituting the vibrator 14 stretches and contracts in a two-dimensional isotropic manner. According to the vibrator 14 in which such piezoelectric films 16 that stretch and contract isotropically and two-dimensionally are laminated, compared to a case where typical piezoelectric films formed of PVDF or the like that stretch and contract greatly in only one direction are laminated, the display panel 12 can be vibrated with a large force, and a louder and more beautiful sound can be output.

As described above, the vibrator 14 of the illustrated example has five layers of such a piezoelectric film 16 laminated. In the vibrator 14 of the illustrated example, the adjacent piezoelectric films 16 are bonded to each other through the bonding layer 20.

Therefore, even in a case where the rigidity of each piezoelectric film 16 is low and the stretching and contracting force thereof is small, the rigidity is increased by laminating the piezoelectric films 16, and the stretching and contracting force as the vibrator 14 is increased. As a result, even in a case where the display panel 12 has a certain degree of rigidity, the vibrator 14 can sufficiently bend the display panel 12 with a large force, sufficiently vibrate the display panel 12 in the thickness direction, and output a sound by the display panel 12.

In addition, in a case where the thickness of the piezoelectric layer 26 increases, the stretching and contracting force of the piezoelectric film 16 is increased, but the driving voltage required for stretching and contracting the film is increased by the same amount. Here, as described above, in the vibrator 14, since the maximum thickness of the piezoelectric layer 26 is preferably approximately 300 μm, the piezoelectric film 16 can be sufficiently stretched and contracted even in a case where the voltage applied to each piezoelectric film 16 is small.

In the image display apparatus 10 according to the embodiment of the present invention, the vibrator is not limited to the laminated piezoelectric element obtained by laminating the piezoelectric film 16 as in the illustrated example. That is, various known vibrators used as a vibrator which vibrates a vibration plate to output a voice, that is, so-called exciters (audio exciters) can be used in the image display apparatus according to the embodiment of the present invention. In particular, a condenser type vibrator in which electrode layers are provided on both surfaces of a piezoelectric body, a piezoelectric layer, or the like is suitably used.

Examples of such a condenser type vibrator include vibrators using ceramic piezoelectric bodies such as PVDF, PZT, PLZT, barium titanate, zinc oxide, BFBT, and piezo elements as disclosed in JP2021-090167A.

Furthermore, one piezoelectric film which is not laminated may be used as the vibrator as long as it has sufficient force to vibrate the display panel 12 due to the stretch and contraction.

As described above, the image display apparatus 10 according to the embodiment of the present invention outputs a voice by mounting the vibrator 14 on the back surface of the display panel 12 and vibrating the display panel 12 as a vibration plate by the vibrator 14.

The image display apparatus 10 of the illustrated example vibrates the display panel 12 as a vibration plate by the stretch and contraction of the condenser type vibrator 14, such as a laminated piezoelectric element in which the piezoelectric film 16 is laminated, and outputs a voice.

Here, in the first aspect of the image display apparatus 10 according to the embodiment of the present invention, the display panel 12 having a pixel pitch of 25 to 100 dpi is used, and in a case where a length of a diagonal line of the display panel 12 is denoted by A, the maximum length Lmax of the vibrator 14 in a direction along a lateral direction of the display panel 12 satisfies “Lmax≤(A/0.15)^{1/2}”.

In addition, in the second aspect of the image display apparatus 10 according to the embodiment of the present invention, the display panel 12 having a pixel pitch of 50 to 200 dpi is used, and in a case where a length of a diagonal line of the display panel 12 is denoted by A, the maximum length Lmax of the vibrator 14 in a direction along a lateral direction of the display panel 12 satisfies “Lmax≤(A/0.3)^{1/2}”.

Furthermore, in the third aspect of the image display apparatus 10 according to the embodiment of the present invention, the display panel 12 having a pixel pitch of 100 to 400 dpi is used, and in a case where a length of a diagonal line of the display panel 12 is denoted by A, the maximum length Lmax of the vibrator 14 in a direction along a lateral direction of the display panel 12 satisfies “Lmax≤(A/0.6)^{1/2}”.

In the present invention, in a case where the shape of the display panel 12 is rectangular, such as a normal (general-purpose) display panel used in a full high definition television, a 4K television, and an 8K television, a direction of a long side is the lateral direction. However, in a case of a display panel in which the long side direction is in a state of being inclined with respect to the horizontal direction, such as being coincident with the vertical direction in a long side direction, even in the same rectangle, in a normal use state of the image display apparatus, the lateral direction is as follows.

In a case of a display panel having various shapes such as a square shape, a circular shape, and an elliptical shape, a horizontal direction in a normal use state in which an image display apparatus using the display panel is appropriately installed is set as the lateral direction of the display panel.

Since the image display apparatus 10 according to the embodiment of the present invention has such a configuration, it is possible to sufficiently output a voice up to a high sound band according to the size and the pixel pitch of the display panel 12.

As described above, in recent years, thin displays such as a liquid crystal display and an organic EL display tend to be enlarged.

However, according to the study of the present inventors, in an image display apparatus which outputs a voice by vibrating a display panel using a vibrator, in a large image display apparatus, even in a case where the image display apparatus is viewed at an appropriate viewing distance, the sound pressure of the voice, particularly, the sound pressure in a high sound band is low, and there is a case in which the voice cannot be heard with an appropriate sound.

Specifically, as shown in FIG. 1, in the image display apparatus in which the vibrators 14 are arranged separately in the right channel and the left channel, in a case where the image display apparatus is viewed from the front of the vibrators 14, a sound from a low sound to a high sound can be appropriately heard.

However, in a case where the image display apparatus is viewed at the center of the screen, the sound pressure of the voice at a high sound band is particularly low, and an appropriate voice cannot be heard.

The present inventors have conducted intensive studies on the phenomenon. As a result, it is found that the cause is a kind of line array effect depending on the length of the vibrator 14 in the lateral direction.

The line array effect is a phenomenon that occurs in a line sound source such as a sound source in which point sound sources such as a normal dynamic speaker are arranged in a straight line (line shape).

Specifically, the line array effect in the line sound source is a phenomenon in which the effective distance of the voice is longer and the directivity is narrower as the line length of the line sound source, that is, the line length L is longer. The line length of the line sound source is, in other words, a length of the line array.

In a case where the display panel 12 is bent and vibrated by the stretch and contraction of the vibrator 14 mounted on the display panel 12 as in the present invention, the display panel 12 is locally bent and deformed with the portion where the vibrator 14 is mounted as a center. Therefore, it is found that, in a case where the vibrator 14 is long, the region which is bent and deformed is also long, and as a result, a kind of line array effect is exhibited. Details thereof will be described below.

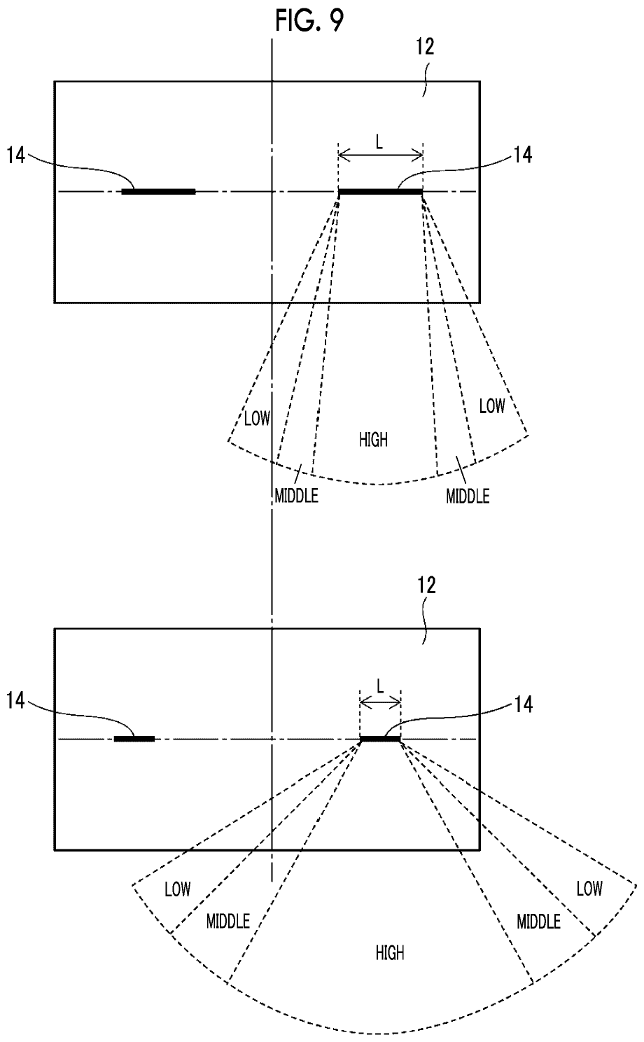

That is, as conceptually shown in the lower part of FIG. 9, in a case where the line length L of the line sound source is short, the directivity is low, and the effective distance of the voice is short. On the other hand, as conceptually shown in the upper part of FIG. 9, in a case where the line length L of the line sound source is increased, the directivity is increased, and the effective distance of the voice is increased.

In addition, as shown in FIG. 9, the sound output, particularly the sound pressure in a high sound band, gradually decreases from the center of the line sound source toward both sides in the line direction.

Therefore, particularly in the large display panel 12, as shown in FIG. 9, in a case where the sound is heard at the center, a case in which the sound pressure in a high sound band is sufficient and a case where the sound pressure in a high sound band is insufficient occur depending on the line length L of the line sound source.

An effective distance CD [m] of the line array effect can be represented by the following expression, in a case where the line length of the line sound source is denoted by L [m] and the frequency of the sound is denoted by f [Hz].

$$CD = ( {L}^{2} \times f ) / 700$$

$$accordingly ,$$

$$L = {[ ( 700 \times CD ) / f ]}^{1 / 2}$$

That is, in the line sound source, as the line length L is longer and the frequency f is higher, that is, in the high sound band, the effective distance CD due to the line array effect is longer, and as a result, the directivity is narrowed.

Here, the vibrator 14 which vibrates the vibration plate bends and vibrates the vibration plate by stretch and contraction at each position in one direction in a linear shape, that is, at each point.

Therefore, a speaker unit using the vibrator 14 and the vibration plate can be regarded as the line sound source. For example, in a case where the striped vibrators 14 as shown in FIGS. 1 and 8 are arranged so that the longitudinal direction of the vibrators 14 and the lateral direction of the display panel 12 match each other, the vibrators 14 can be regarded as a lateral sound source.

As a result, in a case where the line length L of the vibrator 14 is long, as shown in the upper part of FIG. 9, a voice with sufficient sound pressure does not reach the center of the display unit in a high sound band (high frequency band).

Here, in the television, an appropriate viewing distance is determined according to the size of the display panel 12. Specifically, as the size of the display panel 12 is smaller, the appropriate viewing distance is shorter.

In addition, the appropriate viewing distance of the television is shorter as the number of pixels is larger, that is, as the resolution is higher. Therefore, in the full high definition television, the 4K television, and the 8K television, the appropriate viewing distance is the longest in the full high definition television and the shortest in the 8K television.

For example, in a case of 80 inches, the appropriate viewing distance is 3 μm for the full high definition television and 1.5 μm for the 4K television.

In a case of 65 inches, the appropriate viewing distance is 2.5 μm for the full high definition television and 1.2 μm for the 4K television.

In a case of 55 inches, the appropriate viewing distance is 2 μm for the full high definition television and 1 μm for the 4K television.

Furthermore, in a case of 42 inches, the appropriate viewing distance is 1.5 μm for the full high definition television and 0.8 μm for the 4K television.

That is, in the image display apparatus 10, basically, a sufficient sound pressure may be obtained from a low sound band to a high sound band at an appropriate viewing distance according to the resolution and the size of the television (display panel).

Here, by using the above-described expression for calculating the effective distance of the line array effect, a frequency f at which the line array effect occurs at the appropriate viewing distance can be calculated in accordance with the line length L of the vibrator 14 by replacing the appropriate viewing distance according to the size of the television (display panel) with the effective distance CD of the line array effect.

For example, in a case of the vibrator 14 having a line length L of 0.18 m, frequencies at which the line array effect is exhibited at an appropriate viewing distance for each size are as follows for the 4K television and the full high definition television (FHD).

TABLE 1
Line length L = 0.18 m

| | |
|---|---|
| 4K | FHD |

| | Viewing | | Viewing | |
|---|---|---|---|---|
| Number of | distance | Frequency | distance | Frequency |
| inches | [m] | [kHz] | [m] | [kHz] |
| 80 | 1.5 | 32 | 3 | 65 |
| 65 | 1.2 | 26 | 2.5 | 54 |
| 55 | 1 | 22 | 2 | 43 |
| 50 | 0.9 | 19 | 1.9 | 41 |
| 42 | 0.8 | 17 | 1.5 | 32 |
| 37 | 0.7 | 15 | 1.4 | 30 |
| 32 | 0.6 | 13 | 1.2 | 26 |
| 26 | 0.5 | 11 | 1 | 22 |
| 23 | 0.45 | 10 | 0.9 | 19 |

In addition, in a case of a vibrator having a line length L of 0.20 m, frequencies at which the line array effect is exhibited at the viewing distance in each size are as follows for the 4K television and the full high definition television (FHD).

TABLE 2
Line length L = 0.20 m

| | |
|---|---|
| 4K | FHD |

| | Viewing | | Viewing | |
|---|---|---|---|---|
| Number of | distance | Frequency | distance | Frequency |
| inches | [m] | [kHz] | [m] | [kHz] |
| 80 | 1.5 | 26 | 3 | 53 |
| 65 | 1.2 | 21 | 2.5 | 44 |
| 55 | 1 | 18 | 2 | 35 |
| 50 | 0.9 | 16 | 1.9 | 33 |
| 42 | 0.8 | 14 | 1.5 | 26 |
| 37 | 0.7 | 12 | 1.4 | 25 |
| 32 | 0.6 | 11 | 1.2 | 21 |
| 26 | 0.5 | 9 | 1 | 18 |
| 23 | 0.45 | 8 | 0.9 | 16 |

Here, in many human ears, particularly in a case of television use, a high frequency sound band with a frequency of 16 kHz or more does not have a significant effect on sound quality even in a case where the sound is not heard. In other words, in the high sound band with a frequency of 16 kHz or more, there is no significant problem in sound quality even in a case where the line array effect is exhibited and the directivity is narrowed.

Therefore, in a case where the frequency at which the line array effect is exhibited at the appropriate viewing distance is 16 kHz or more, the line array effect is not exhibited in a sound with a frequency of less than 16 kHz at the appropriate viewing distance, and thus, a sufficiently wide directivity can be obtained even in a high sound band in practical use.

That is, in the case of the vibrator having a line length L of 0.18 m, in the 4K television, the line array effect is not exhibited in the sound with a frequency of less than 16 kHz at the appropriate viewing distance, in a case where the display panel is 42 inches or more. Therefore, in the case of the vibrator having a line length L of 0.18 μm along the lateral direction of the display panel, in the 4K television, a sufficient sound pressure can be obtained from the low sound band to the high sound band at the appropriate viewing distance in the center of the display panel, in a case where the display panel is 42 inches or more.

In addition, in the case of the vibrator having the line length L of 0.18 m, in the full high definition television, the line array effect is not exhibited in the sound with a frequency of less than 16 kHz at the appropriate viewing distance, in a case of all sizes of 23 inches or more.

Therefore, in the case of the vibrator having a line length L of 0.18 μm along the lateral direction of the display panel, in the full high definition television, a sufficient sound pressure can be obtained from the low sound band to the high sound band at the appropriate viewing distance in the center of the display panel, in a case of all display panels of 23 inches or more.

On the other hand, in the case of the vibrator having a line length L of 0.20 m, in the 4K television, the line array effect is not exhibited in the sound with a frequency of less than 16 kHz at the appropriate viewing distance, in a case where the display panel is 50 inches or more.

Therefore, in the case of the vibrator having a line length L of 0.20 μm along the lateral direction of the display panel, in the 4K television, a sufficient sound pressure can be obtained from the low sound band to the high sound band at the appropriate viewing distance in the center of the display panel, in a case where the display panel is 50 inches or more.

In addition, even in the case of the vibrator having the line length L of 0.20 m, in the full high definition television, the line array effect is not exhibited in the sound with a frequency of less than 16 kHz at the appropriate viewing distance, in a case of all sizes of 23 inches or more.

Therefore, even in the case of the vibrator having a line length L of 0.20 μm along the lateral direction of the display panel, in the full high definition television, a sufficient sound pressure can be obtained from the low sound band to the high sound band at the appropriate viewing distance in the center of the display panel, in a case of all display panels of 23 inches or more.

The present inventor changes the line length L of the vibrator 14 from 0.1 μm to 0.33 m in increments of 0.01 μm, and calculates the frequency at which the line array effect is exhibited at the appropriate viewing distance for each size of 23 to 80 inches for each of the full high definition television, the 4K television, and the 8K television.

As a result, in each size of the display panel of each resolution, the maximum line length L (maximum line length) of the vibrator 14 with the frequency at which the line array effect is exhibited is 16 kHz or more at the appropriate viewing distance is detected. In other words, for each size of the display panel of each resolution, at the appropriate viewing distance, the maximum line length L of the vibrator 14 at which the line array effect is not exhibited below 16 kHz is detected.

The results are shown in the following table.

TABLE 3

| | | FHD | | 4K | | 8K | |
|---|---|---|---|---|---|---|---|
| | Diagonal | Maximum line | | Maximum line | | Maximum line | |
| Number of | line | length | | length | | length | |
| inches | [cm] | [cm] | | [cm] | | [cm] | |
| 80 | 203 | 36 | 0.16 | 26 | 0.30 | 18 | 0.60 |
| 65 | 165 | 33 | 0.15 | 23 | 0.31 | 17 | 0.60 |
| 55 | 140 | 30 | 0.16 | 21 | 0.32 | 15 | 0.60 |
| 50 | 127 | 29 | 0.15 | 20 | 0.32 | 15 | 0.60 |
| 42 | 107 | 26 | 0.16 | 19 | 0.30 | 13 | 0.60 |
| 37 | 94 | 25 | 0.15 | 18 | 0.29 | 13 | 0.60 |
| 32 | 81 | 23 | 0.15 | 16 | 0.32 | 12 | 0.60 |
| 26 | 66 | 21 | 0.15 | 15 | 0.29 | 10 | 0.60 |
| 23 | 56 | 20 | 0.15 | 14 | 0.30 | 10 | 0.60 |

As shown in the table, for example, in a case where the size of the display panel 12 is 80 inches, the line length L of the vibrator 14 is 36 cm or less for full high definition, the line length L of the vibrator 14 is 26 cm or less for the 4K television, and the line length L of the vibrator 14 is 18 cm or less for the 8K television, the line array effect is not exhibited at a frequency of less than 16 kHz at the appropriate viewing distance.

In addition, for example, in a case where the size of the display panel 12 is 50 inches, the line length L of the vibrator 14 is 29 cm or less for full high definition, the line length L of the vibrator 14 is 20 cm or less for the 4K television, and the line length L of the vibrator 14 is 15 cm or less for the 8K television, the line array effect is not exhibited at a frequency of less than 16 kHz at the appropriate viewing distance.

Here, as a result of examining the table, the present inventors have obtained the following findings.

Specifically, it is found that a value obtained by dividing the length (unit: cm) of the diagonal line in each size by the square of the maximum line length (unit: cm) is approximately 0.15 for the full high definition display panel, approximately 0.3 for the 4K television display panel, and approximately 0.6 for the 8K television display panel. That is, in the full high definition display panel, regardless of any size, the length (unit: cm) of the diagonal line is divided by a coefficient of 0.15 and raised to ½ power (root multiplication), and thus the maximum line length (unit: cm) of the vibrator 14 at which the line array effect is not exhibited at a frequency of less than 16 kHz at the appropriate viewing distance is obtained.

In addition, in the 4K television display panel, regardless of any size, the length (unit: cm) of the diagonal line is divided by a coefficient of 0.3 and raised to ½ power, and thus the maximum line length (unit: cm) of the vibrator 14 at which the line array effect is not exhibited at a frequency of less than 16 kHz at the appropriate viewing distance is obtained.

Furthermore, in the 8K television display panel, regardless of any size, the length (unit: cm) of the diagonal line is divided by a coefficient of 0.6 and raised to ½ power, and thus the maximum line length (unit: cm) of the vibrator 14 at which the line array effect is not exhibited at a frequency of less than 16 kHz at the appropriate viewing distance is obtained.

That is, by setting the maximum line length (unit: cm) of the vibrator 14 to be equal to or less than the maximum line length (unit: cm) calculated by the expression, the line array effect is not exhibited in the voice with a frequency of less than 16 kHz at the appropriate viewing distance.

The present invention has been made by obtaining the above finding, and in the first aspect of the image display apparatus 10 according to the embodiment of the present invention, the display panel 12 having a pixel pitch of 25 to 100 dpi is used, and in a case where a length of a diagonal line of the display panel 12 is denoted by A (cm), the maximum length Lmax (cm) of the vibrator 14 in a direction along a lateral direction of the display panel 12 satisfies “Lmax≤(A/0.15)^{1/2}”. The display panel 12 having a pixel pitch of 25 to 100 dpi is a display panel corresponding to the full high definition television.

In addition, in the second aspect of the image display apparatus 10 according to the embodiment of the present invention, the display panel 12 having a pixel pitch of 50 to 200 dpi2 is used, and in a case where a length of a diagonal line of the display panel 12 is denoted by A (cm), the maximum length Lmax (cm) of the vibrator 14 in a direction along a lateral direction of the display panel 12 satisfies “Lmax≤(A/0.3)^{1/2}”. The display panel 12 having a pixel pitch of 50 to 200 dpi2 is a display panel corresponding to the 4K television.

Furthermore, in the third aspect of the image display apparatus 10 according to the embodiment of the present invention, the display panel 12 having a pixel pitch of 100 to 400 dpi is used, and in a case where a length of a diagonal line of the display panel 12 is denoted by A (cm), the maximum length Lmax (cm) of the vibrator 14 in a direction along a lateral direction of the display panel 12 satisfies “Lmax≤(A/0.6)^{1/2}”. The display panel 12 having a pixel pitch of 100 to 400 dpi is a display panel corresponding to the 8K television.

The image display apparatus according to the embodiment of the present invention has such a configuration, and thus, the frequency at which the line array effect is exhibited can be set to 16 kHz or more, having less influence on the sound quality of the high sound band, at the appropriate viewing distance, depending on the resolution and the size of the display panel 12.

As a result, with the image display apparatus according to the embodiment of the present invention, in the image display apparatus which outputs a voice by vibrating the display panel 12 by the vibrator 14, it is possible to obtain a sufficient sound pressure from a low sound band to a high sound band in practice at an appropriate viewing distance at the center of the display panel.

In the example shown in FIG. 1 (FIG. 9), the striped vibrator 14 is disposed such that the longitudinal direction thereof coincides with the lateral direction of the display panel 12, but the present invention is not limited thereto.

In the image display apparatus according to the embodiment of the present invention, for example, the longitudinal direction of the striped vibrator 14 may be disposed to be inclined with respect to the lateral direction of the display panel 12. Even in this case, the maximum length Lmax of the vibrator 14 is not the length of the vibrator 14 in the longitudinal direction in the form of a strip and the length from the end part to the end part of the vibrator 14 in the direction along the lateral direction of the display panel 12, but is the maximum length of the vibrator 14 in the direction along the lateral direction of the display panel 12.

That is, in the image display apparatus according to the embodiment of the present invention, the maximum length Lmax of the vibrator 14 is the maximum length of the vibrator 14 in the direction along the lateral direction of the display panel 12, regardless of the shape of the vibrator, the disposition state on the display panel 12, and the like.

Hereinbefore, the image display apparatus according to the embodiment of the present invention has been described in detail, but the present invention is not limited to the above-described examples and various improvements and changes can be made without departing from the spirit of the present invention.

### EXAMPLES

Hereinafter, the present invention will be described in more detail with reference to specific examples of the present invention.

### [Production of Piezoelectric Film]

A piezoelectric film shown in FIG. 4 was produced by the methods shown in FIGS. 5 to 7.

First, cyanoethylated PVA (CR-V, manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.
PZT Particles: 300 parts by mass
Cyanoethylated PVA: 30 parts by mass
DMF: 70 parts by mass

PZT particles which were obtained by sintering mixed powder, formed by wet-mixing powder of a Pb oxide, a Zr oxide, and a Ti oxide as main components using a ball mill such that the amount of Zr and the amount of Ti respectively reached 0.52 moles and 0.48 moles with respect to 1 mole of Pb, at 800° C. for 5 hours and being subjected to a crushing treatment were used as the PZT particles.

On the other hand, two sheets of sheet-like materials obtained by performing vacuum vapor deposition on a copper thin film having a thickness of 0.1 μm were prepared on a PET film having a thickness of 4 μm. That is, in the present example, the first electrode layer and the second electrode layer were copper-deposited thin films having a thickness of 0.1 μm, and the first protective layer and the second protective layer were PET films having a thickness of 4 μm.

The copper thin film (second electrode layer) of one sheet-like material was coated with the coating material for forming a piezoelectric layer, which was prepared in advance, using a slide coater.

Next, the material obtained by coating the sheet-like material with the coating material was heated and dried on a hot plate at 120° C. to evaporate DMF. In this manner, a laminate in which the second electrode layer made of copper was provided on the second protective layer made of PET and the piezoelectric layer (polymer-based piezoelectric composite material layer) having a thickness of 50 μm was formed thereon was produced.

The produced piezoelectric layer (laminate) was subjected to a calender treatment using a heating roller pair. A temperature of the heating roller pair was set to 100° C.

After performing the calender treatment, the produced piezoelectric layer was subjected to a polarization treatment in a thickness direction.

The other sheet-like material was laminated on the laminate facing the copper thin film (first electrode layer) toward the piezoelectric layer.

Next, the laminate of the laminate and the sheet-like material was subjected to thermal compression bonding at a temperature of 120° C. using a heating roller pair to adhere the piezoelectric layer and the first electrode layer, thereby producing a piezoelectric film as shown in FIG. 4.

### Example

The produced piezoelectric film was cut into a rectangle having a size of 22×18 cm.

The piezoelectric film was provided with a bonding layer, and then folded and pressed with a roller to be bonded to each other, and this operation was repeated four times at intervals of 4 cm in a direction of 22 cm. As a result, a vibrator having a rectangular planar shape of 4×18 cm as shown in FIG. 8 was produced by laminating five layers of the piezoelectric film and bonding the piezoelectric films laminated adjacent to each other. Therefore, in the vibrator, the side having a length of 18 cm is a ridge line (folding-back line). In the laminated vibrator, a 2 cm piezoelectric film surplus (redundant portion) was generated at an end portion, and the wiring line was connected using this redundant portion (refer to FIG. 8). Regard this point, the same applies to Comparative Example.

As the bonding layer, a hot melt sheet (CRANBERRY; thickness: 30 m) manufactured by KURABO INDUSTRIES LTD. was used.

A PET panel having a thickness of 0.5 mm and a size of 121×69 cm was prepared. The PET panel has the same size as a 55-inch display panel.

The produced vibrator was bonded to a region at the center of the panel in the up-down direction (width direction) and at a distance of 30 cm from one end part in the lateral direction (longitudinal direction). A double-sided pressure-sensitive adhesive tape (TESA 70420; thickness: 200 m) manufactured by tesa SE was used for the bonding. The redundant portion was not bonded in order to connect the wiring line. Regard this point, the same applies to Comparative Example.

The panel and the vibrator were bonded to each other by matching the longitudinal direction and the lateral direction of each other and matching the center of the panel in the up-down direction with the center of the vibrator (rectangle) at a position 15 cm from one end part.

That is, in the present example, in a case where the PET panel was regarded as a display panel, the maximum length Lmax of the vibrator along the lateral direction of the display panel was 18 cm.

In addition, in a case where the PET panel was regarded as a display panel of a 55-inch 4K television, the length A of the diagonal line was 140 cm, so that (140/0.3)^{1/2}=21.6, that is, “Lmax≤(A/0.3)^{1/2}” was satisfied.

### Comparative Example

The produced piezoelectric film was cut into a rectangle of 22×25 cm, and folded four times at an interval of 4 cm in a direction of 22 cm in the same manner as in Example, thereby producing a vibrator shown in FIG. 8, having a planar shape of a rectangle of 4×25 cm. Therefore, in the vibrator, the side having a length of 25 cm is a ridge line (folding-back line).

The vibrator was bonded to the same PET panel as in Example in the same manner as in Example.

That is, in the present example, in a case where the PET panel was regarded as a display panel, the maximum length Lmax of the vibrator along the lateral direction of the display panel was 25 cm.

In addition, in a case where the PET panel was regarded as a display panel of a 55-inch 4K television, the length A of the diagonal line was 140 cm, so that (140/0.3)^{1/2}=21.6, that is, “Lmax≤(A/0.3)^{1/2}” was not satisfied.

### Evaluation

The PET panel to which the vibrator was bonded was regarded as a display panel of a 55-inch 4K television, and frequency characteristics of the sound pressure were measured.

An appropriate viewing distance of the 4K television having a size of 55 inches was 1 m. Accordingly, a microphone was installed at a position of 1 μm from the center of the display panel in the normal direction (direction perpendicular to the display panel=PET panel), and the frequency characteristics of the sound pressure output by the display panel were measured.

An input signal to the vibrator was a sine sweep signal (50 Vrms).

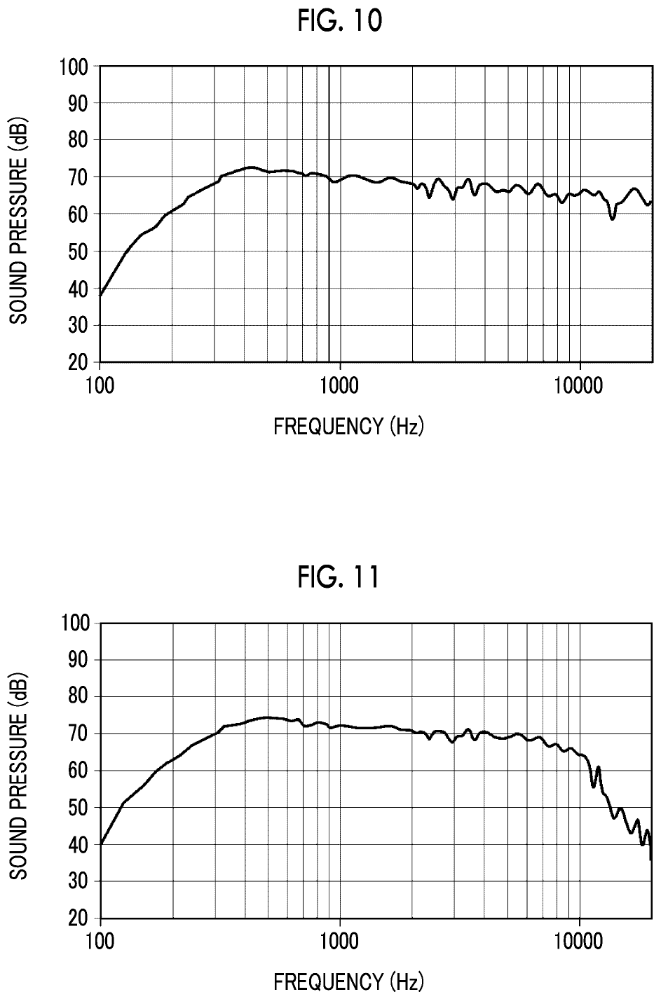

FIG. 10 shows the sound pressure measurement results of Example; and FIG. 11 shows the sound pressure measurement results of Comparative Example.

As in Example, in a case where the maximum line length (line length L) of the vibrator was 18 cm and the viewing distance (effective distance CD) was 1 μm, the line array effect was exhibited at 22 kHz or more at the position of the viewing distance of 1 μm from the above-described expression “CD=(L²×f)/700”.

Therefore, in Examples satisfying “Lmax≤(A/0.3)^{1/2}”, as shown in FIG. 10, in a case where the frequency characteristics were measured at a distance of 1 μm, a decrease in sound pressure was not observed in a high sound band up to 20 kHz.

On the other hand, as in Comparative Example, in a case where the maximum line length (line length L) of the vibrator was 25 cm, the line array effect was exhibited at a position of a viewing distance of 1 μm at 11 kHz or more.

Therefore, in Comparative Example which did not satisfy “Lmax≤(A/0.3)^{1/2}”, as shown in FIG. 11, in a case where the frequency characteristics were measured at a distance of 1 μm, the sound pressure was decreased at 11 kHz or more, and the sound pressure in a high sound band was insufficient.

The reason why the sound pressure in the middle and low sound bands was higher in Comparative Example is that the vibrator of Comparative Example had a larger area.

From the above results, the effect of the present invention is clear.

The present invention can be suitably used for a thin television or the like.

### EXPLANATION OF REFERENCES

10: image display apparatus
12: display panel
14: vibrator
16: piezoelectric film
20, 68: bonding layer
26: piezoelectric layer
28: first electrode layer
30: second electrode layer
32: first protective layer
34: second protective layer
38: polymer matrix
40: piezoelectric particle
42a, 42b: sheet-like material
46: laminate
72: first lead-out wire
74: second lead-out wire

What is claimed is:

1. An image display apparatus comprising:
a display panel having a pixel pitch of 25 to 100 dpi; and
a vibrator mounted on a non-display surface of the display panel,
wherein, in a case where a length of a diagonal line of the display panel is denoted by A, a maximum length Lmax of the vibrator in a direction along a lateral direction of the display panel satisfies Lmax≤(A/0.15)^{1/2}.

2. An image display apparatus comprising:
a display panel having a pixel pitch of 50 to 200 dpi; and
a vibrator mounted on a non-display surface of the display panel,
wherein, in a case where a length of a diagonal line of the display panel is denoted by A, a maximum length Lmax of the vibrator in a direction along a lateral direction of the display panel satisfies Lmax≤(A/0.3)^{1/2}.

3. An image display apparatus comprising:
a display panel having a pixel pitch of 100 to 400 dpi; and
a vibrator mounted on a non-display surface of the display panel,
wherein, in a case where a length of a diagonal line of the display panel is denoted by A, a maximum length Lmax of the vibrator in a direction along a lateral direction of the display panel satisfies Lmax≤(A/0.6)^{1/2}.

4. The image display apparatus according to claim 1,
wherein an aspect ratio of the display panel is 16:9.

5. The image display apparatus according to claim 1,
wherein the vibrator is a piezoelectric film having electrode layers on both surfaces of a piezoelectric layer.

6. The image display apparatus according to claim 5,
wherein the vibrator is obtained by laminating a plurality of layers of the piezoelectric film.

7. The image display apparatus according to claim 5,
wherein the piezoelectric film has a protective layer which covers the electrode layer.

8. The image display apparatus according to claim 5,
wherein the piezoelectric layer is a polymer-based piezoelectric composite material having piezoelectric particles in a polymer material.

9. The image display apparatus according to claim 8,
wherein the polymer material has a cyanoethyl group.

10. The image display apparatus according to claim 9,
wherein the polymer material is cyanoethylated polyvinyl alcohol.

11. The image display apparatus according to claim 6,
wherein the vibrator is obtained by folding one piezoelectric film to laminate the plurality of layers of the piezoelectric film.

12. The image display apparatus according to claim 6,
wherein laminated adjacent piezoelectric films are bonded to each other by a bonding layer.

13. The image display apparatus according to claim 2,
wherein an aspect ratio of the display panel is 16:9.

14. The image display apparatus according to claim 3,
wherein an aspect ratio of the display panel is 16:9.

15. The image display apparatus according to claim 2,
wherein the vibrator is a piezoelectric film having electrode layers on both surfaces of a piezoelectric layer.

16. The image display apparatus according to claim 3,
wherein the vibrator is a piezoelectric film having electrode layers on both surfaces of a piezoelectric layer.

17. The image display apparatus according to claim 15,
wherein the vibrator is obtained by laminating a plurality of layers of the piezoelectric film.

18. The image display apparatus according to claim 16,
wherein the vibrator is obtained by laminating a plurality of layers of the piezoelectric film.

19. The image display apparatus according to claim 15,
wherein the piezoelectric film has a protective layer which covers the electrode layer.

20. The image display apparatus according to claim 16,
wherein the piezoelectric film has a protective layer which covers the electrode layer.
